(19) United States
(12) Patent Application Publication
(10) Pub. No.: US 2023/0352321 A1
(43) Pub. Date: Nov. 2, 2023

(54) WET PROCESSING OF MICROELECTRONIC SUBSTRATES WITH CONTROLLED MIXING OF FLUIDS PROXIMAL TO SUBSTRATE SURFACES

(71) Applicant: TEL MANUFACTURING AND ENGINEERING OF AMERICA, INC., Chaska, MN (US)

(72) Inventors: Thomas J. Wagener, Shorewood, MN (US); Jeffery W. Butterbaugh, Eden Prairie, MN (US); David P. DeKraker, Burnsville, MN (US)

(21) Appl. No.: 18/220,004

(22) Filed: Jul. 10, 2023

Related U.S. Application Data
(63) Continuation of application No. 13/083,948, filed on Apr. 11, 2011, now abandoned.
(60) Provisional application No. 61/328,274, filed on Apr. 27, 2010.

(51) Int. Cl. H01L 21/67

(52) U.S. Cl. CPC H01L 21/6708; H01L 21/67051

(57) ABSTRACT

The present invention provides methods and apparatuses for controlling the transition between first and second treatment fluids during processing of microelectronic devices using spray processor tools.

### PRIORITY

The present non-provisional patent Application claims the benefit of U.S. Provisional Patent Application having Ser. No. 61/328,274, filed on Apr. 27, 2010, by Wagener et al. and titled WET PROCESSING OF MICROELECTRONIC SUBSTRATES WITH CONTROLLED MIXING OF FLUIDS PROXIMAL TO SUBSTRATE SURFACES, wherein the entirety of said provisional patent application is incorporated herein by reference.

### FIELD OF THE INVENTION

The present invention relates to processing microelectronic devices using spray processor tools. More particularly, the present invention relates to controlling the mixing of treatment fluids that might occur proximal to substrate surfaces during processing when using spray processor tools to minimize feature damage that can otherwise occur from uncontrolled mixing.

### BACKGROUND

The microelectronic industry relies on a variety of process recipes in the manufacture of a variety of microelectronic devices. Process recipes often involve one or both of wet and dry processing. The microelectronic industry can utilize a variety of configured systems to carry out such processes. Many such systems are in the form of spray processor tools. A spray processor tool generally refers to a tool in which treatment fluids such as chemicals, rinsing liquids, gases, and combinations thereof are sprayed, cast, or otherwise dispensed onto a microelectronic workpiece either singly or in combination in a series of one or more steps. This is in contrast to wet bench tools where microelectronic workpieces are immersed in a fluid bath during the course of processing.

In a typical spray processor tool, treatment fluid is dispensed or otherwise sprayed onto microelectronic workpiece(s) while the microelectronic workpiece(s) are supported within a process chamber of the spray processor tool. Often, the microelectronic workpiece(s) are spinning about an axis during one or more portions of such a treatment. In single microelectronic workpiece systems, the microelectronic workpiece often rotates about its own central axis. An exemplary tool of this type is commercially available under the trade designation ORION® from FSI International, Inc., Chaska, MN. In tools that process a plurality of microelectronic workpieces simultaneously, the microelectronic workpieces often may be stored in holders (also referred to as cassettes) that are supported upon a rotating turntable (also referred to as a platen). The turntable rotates about its own central axis, and, schematically, the holders spin in orbit around the axis of the turntable in a planetary manner. Exemplary tools of this type are commercially available under the respective trade designations MERCURY® and ZETA® from FSI International, Inc., Chaska, MN.

Typical recipes for spray processor tools include process steps involving subjecting a microelectronic workpiece to one or more wet processes such as those including one or more chemical treatments, rinsing treatments, and combinations thereof. Typically after the desired wet processing is completed, the microelectronic workpiece is dried. For example, a conventional rinse and dry sequence involves first dispensing or otherwise spraying a rinsing liquid onto a microelectronic workpiece supported on a rotating turntable in a process chamber. Rinsing is stopped and the plumbing used to deliver the rinse liquid is then purged into the process chamber. A drying gas is then typically introduced into the chamber through the same or different plumbing to dry the microelectronic workpiece.

According to an exemplary fabrication strategy, photoresist masks are used to help form device features on microelectronic substrates. These features have tended to become smaller as microelectronic technology advances. For example, some current devices include features such as gate structures having nanometer-scale dimensions. Unfortunately, smaller device features tend to be more susceptible to damage in the course of fabrication than larger, more robust features. It would be desirable to develop processing strategies that help protect small device features in the course of fabrication.

After a photoresist mask has been used to help make features, the mask usually is removed. Removal of photoresist masks is a context in which feature damage is an issue. The well-known piranha treatment is one strategy that is used to remove photoresist residue from substrate surfaces. A typical piranha composition is an aqueous solution obtained by combining ingredients including at least sulfuric acid and hydrogen peroxide. Often, these ingredients are supplied as concentrated, aqueous sulfuric acid and a 30 weight percent, aqueous hydrogen peroxide. A typical piranha solution is obtained by combining about 2 to about 10 parts by volume of the acid solution per volume of the hydrogen peroxide solution. The solutions can be used in more dilute form as well. The piranha solution often is used hot, e.g., at a temperature above about 60° C., even above about 80° C., even about 180° C. The piranha solution cleans organic compounds such as photoresist residue from surfaces. The solution also tends to oxidize and hydroxylate metals, rendering them hydrophilic. After cleaning with this solution, the substrate is rinsed well with water. The substrate can then be subjected to further processing as desired.

In other illustrative modes of practice, the cleaning composition may include one or more other acids such as phosphoric acid. Additionally, some cleaning chemistries use acid but do not use peroxide. Some cleaning chemistries may substitute other oxidizing agent(s) for hydrogen peroxide.

Unfortunately, conventional strategies for using such cleaning chemistries may tend to damage device features. The risk becomes greater with smaller features. Other treatments also pose a similar risk of damaging device features. Examples of these other contexts include aqua regia treatment (mixture of nitric acid and hydrochloric acid) for removing metals. Accordingly, improved strategies to protect device features from damage during processing are strongly desired.

### SUMMARY OF THE INVENTION

The present invention dramatically reduces feature damage by controlling and/or preventing the mixing of different chemicals proximal to the surface of an in-process microelectronic workpiece. The present invention is based at least in part upon the appreciation that different chemicals can mix exothermically. This releases energy that can damage fine features on an in-process microelectronic workpiece if the mixing occurs proximally to the workpiece surface. Processing tools that include at least two independent (distinct) nozzles (hereinafter multi-nozzle systems) can dispense at least two different treatment fluids independently onto one more microelectronic workpieces during the course of a multi-step treatment. Such tools are particularly susceptible to the risk of chemicals mixing exothermically on a workpiece surface such as when chemical drips from one nozzle while chemical is dispensed from another nozzle. Accordingly, the principles of the present invention are preferably and advantageously implemented with respect to such multi-nozzle tools.

The present invention provides different strategies to control and/or prevent chemical mixing proximal to workpiece surfaces. According to one approach, the present invention controls the transition between a first chemical dispense and a second chemical dispense to avoid drips of one fluid from a first nozzle from falling onto a surface film of a second fluid being dispensed from a second nozzle. For instance, drops of residual acid from a chemical dispense are prevented from dripping onto the workpiece surface from a first nozzle while rinsing water is being dispensed through a second nozzle in a subsequent processing stage. This can be practiced in one mode by applying suction to the first nozzle before the water is dispensed through the second nozzle. In an additional aspect, the second fluid is introduced onto a workpiece through the second nozzle while suction is maintained on the first nozzle. According to an additional strategy, the second chemical is introduced generally onto the center of the workpiece while the workpiece spins about its own central axis to help further avoid the risk of damage.

In one aspect, the present invention relates to a method of processing a microelectronic workpiece, the method comprising the steps of positioning a microelectronic workpiece in a process chamber comprising first and second dispense nozzles the first and second dispense nozzles configured to independently direct one or more treatment fluids at the microelectronic workpiece; dispensing a first treatment fluid into the process chamber with the first dispense nozzle; terminating dispensing of the first treatment fluid into the process chamber with the first dispense nozzle; applying suction to the first dispense nozzle; and after applying suction to the first dispense nozzle, dispensing a second treatment fluid into the process chamber with the second dispense nozzle.

In another aspect, the present invention relates to a method of processing a microelectronic workpiece, the method comprising the steps of positioning the microelectronic workpiece in a process chamber comprising first and second dispense orifices and the first and second dispense orifices configured to independently direct one or more treatment fluid at the microelectronic workpiece; dispensing a first treatment fluid into the process chamber with the first dispense orifice; applying suction to the first dispense orifice; and after applying suction to the first dispense orifice, dispensing a second treatment fluid into the process chamber with the second dispense orifice.

In another aspect, the present invention relates to a method of processing a microelectronic workpiece, the method comprising the steps of positioning a microelectronic workpiece in a process chamber comprising a first nozzle comprising at least one orifice through which a first treatment fluid can be dispensed into the process chamber and a second nozzle distinct from the first nozzle and comprising at least one orifice through which a second treatment fluid can be dispensed into the process chamber; and applying suction to one or both of the first and second nozzles thereby drawing the respective treatment fluid upstream from the one or both of the first and second nozzles.

In another aspect, the present invention relates to a method of processing a microelectronic device, the method comprising the steps of positioning a microelectronic workpiece in a process chamber comprising first and second dispense nozzles the first and second dispense nozzles configured to independently direct one or more treatment fluid at the microelectronic workpiece; dispensing a first treatment fluid into the process chamber with the first dispense nozzle; dispensing a second treatment fluid into the process chamber with the second dispense nozzle; controlling the transition between a first chemical dispense and a second chemical dispense to avoid drips of one fluid from a first nozzle from falling onto a surface film of a second fluid being dispensed from a second nozzle; and controlling the transition between dispensing the first treatment fluid and dispensing the second treatment fluid to avoid dripping of the first treatment fluid from the first nozzle from falling onto a surface film of the second treatment fluid on the microelectronic workpiece.

### BRIEF DESCRIPTION OF THE DRAWINGS

The accompanying drawings, which are incorporated in and constitute a part of this disclosure, illustrate several aspects of the present invention and together with description of the exemplary embodiments serve to explain the principles of the invention. A brief description of the drawings is as follows:

FIGS. 1-3 schematically illustrate the concept of a microburst as contemplated in accordance with the present invention.

FIG. 4 schematically shows an exemplary apparatus that can be used in accordance with the present invention.

FIGS. 5-12 schematically show a sequence of steps of a prior art process that can be performed by the exemplary apparatus shown in FIG. 4.

FIGS. 13-21 show how the apparatus of FIG. 4 can be used to carry out a sequence of steps incorporating controlled mixing in accordance with the present invention.

### DETAILED DESCRIPTION OF PRESENTLY PREFERRED EMBODIMENTS

The exemplary embodiments of the present invention described herein are not intended to be exhaustive or to limit the present invention to the precise forms disclosed in the following detailed description. Rather the exemplary embodiments described herein are chosen and described so those skilled in the art can appreciate and understand the principles and practices of the present invention.

In representative embodiments, the invention is desirably practiced with respect to preferred multi-nozzle tools of the type in which a microelectronic workpiece being treated is spinning about its own central axis. A preferred exemplary multi-nozzle tool includes a first nozzle in the form of a spray bar that comprises a plurality of orifices through which first treatment fluid(s) are dispensed across a chord of an underlying spinning microelectronic workpiece. Often this chord corresponds to a diameter or portion of a diameter of the microelectronic workpiece. The multi-nozzle tool also includes a second nozzle through which second treatment fluid(s) can be generally centrally dispensed onto the underlying spinning microelectronic workpiece. Each of the first and/or second treatment fluids independently may be dispensed as a stream in continuous, pulsed fashion, or combinations thereof. Each fluid can also be independently atomized so as to be dispensed as a mist or spray. Atomization can occur via nozzle design, via impact among two or more streams, and/or the like.

Often, the microelectronic workpiece(s) are spinning about an axis during one or more portions of such a treatment. In single microelectronic workpiece systems, the microelectronic workpiece often rotates about its own central axis. An exemplary tool of this type is commercially available under the trade designation ORION® from FSI International, Inc., Chaska, MN. In tools that process a plurality of microelectronic workpieces simultaneously, the microelectronic workpieces often may be stored in holders (also referred to as cassettes) that are supported upon a rotating turntable (also referred to as a platen). The turntable rotates about its own central axis, and, schematically, the holders spin in orbit around the axis of the turntable (in a planetary manner). Exemplary tools of this type are commercially available under the respective trade designations MERCURY® or ZETA® from FSI International, Inc., Chaska, MN.

Without wishing to be bound by theory, a rationale can be suggested to explain the dramatic improvement in damage reduction provided by the present invention. It is known that certain combinations of treatment fluids react exothermically and energetically when mixed together. In the context of fabricating microelectronic devices, acid compositions and rinsing water are an example of such a combination. In a specific example, aqueous sulfuric acid, optionally including an oxidizing agent such as hydrogen peroxide, ozone, and/or the like, mixes quite energetically with water. On the scale of the features encountered on the surface of a microelectronic workpiece, the energy is released with an explosive burst referred to herein as a “microburst.” If a microburst occurs proximal to device features, the blast could damage the features.

The risk of microbursts is relatively high when transitioning from a first chemical such as an acid composition to a second chemical such as water and/or if drips of one chemical fall into a film of another chemical. In the specific case of transitioning from hot piranha solution (aqueous mixture of sulfuric acid and hydrogen peroxide) to water in a multi-nozzle system, the residual hot acid dispensed from one nozzle can drip onto a sheeting water film on the spinning microelectronic workpiece surface while water is being introduced through a different nozzle. A drop of hot acid falling onto the microelectronic workpiece surface can cause a localized, highly energetic reaction that could damage the device features proximal to the site of mixing. The risk may continue not just at the transition to rinsing but also during the course of rinsing if residual acid continues to drip onto the wet microelectronic workpiece surface. Microburst damage potentially could occur as well if drips of water mix with an acid rich phase at the workpiece surface.

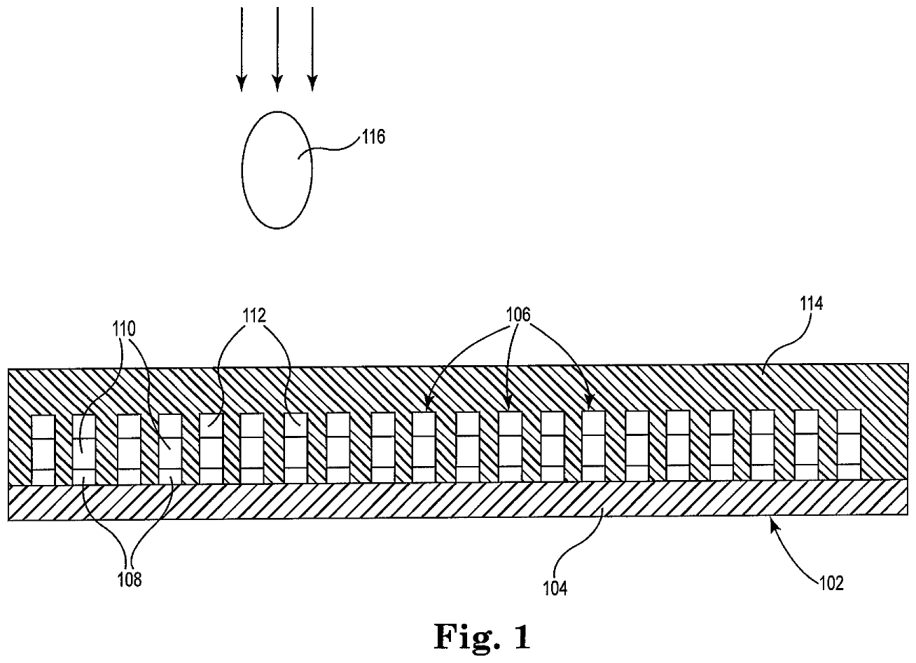

FIGS. 1 through 3 schematically illustrate the concept of how a microburst could damage device features. Referring first to FIG. 1, microelectronic workpiece 102 generally includes a support 104 often comprising a semiconductor microelectronic wafer. Optional additional layers (not shown) such as oxide layers or the like also may be incorporated into support 104 in accordance with conventional practices. Line features 106 in the illustrative form of polysilicon gates are formed on the surface of the support 104. An exemplary embodiment of line features 106 generally includes a gate oxide 108, polysilicon electrode 110, and dielectric layer 112. A film 114 of water overlies the microelectronic workpiece surface, as illustrated. A drop 116 of hot acid is schematically shown falling toward the microelectronic workpiece 102.

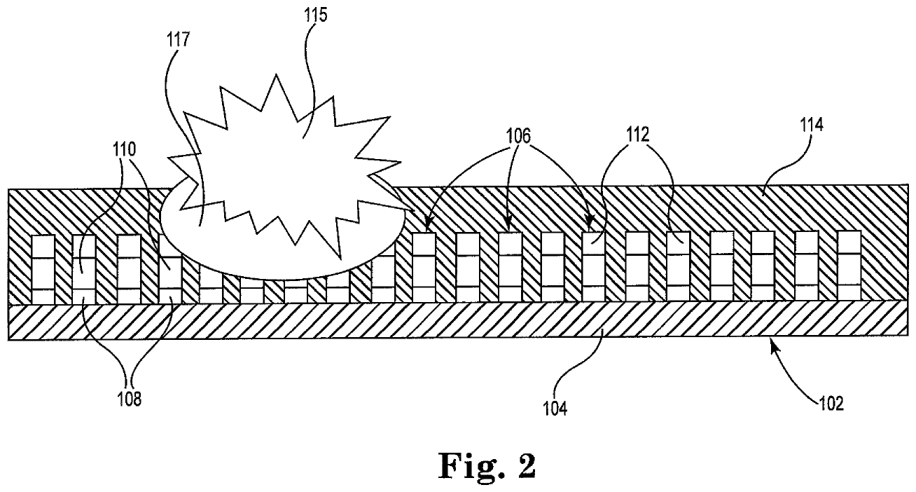

FIG. 2 schematically illustrates the microburst 115 occurring when the drop 116 of hot acid hits the water film 114. The blast zone 117 resulting from the microburst 115 is shown impacting the line features 106.

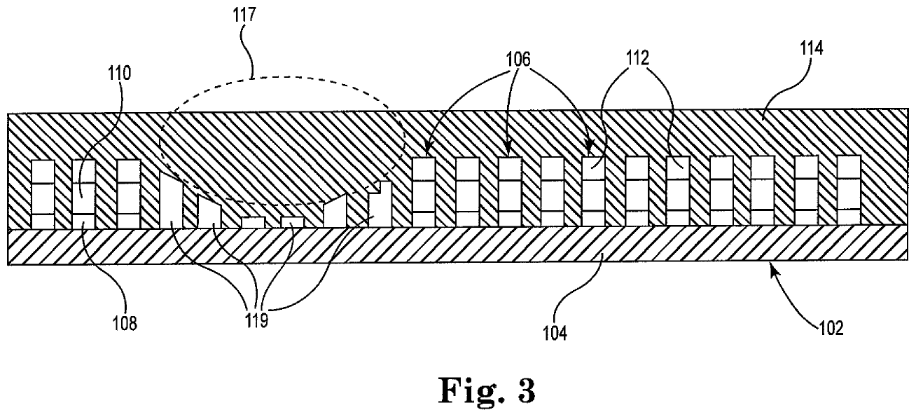

FIG. 3 shows the blast zone 117 after the microburst subsides. Damaged line features 119 are shown in the blast zone 117.

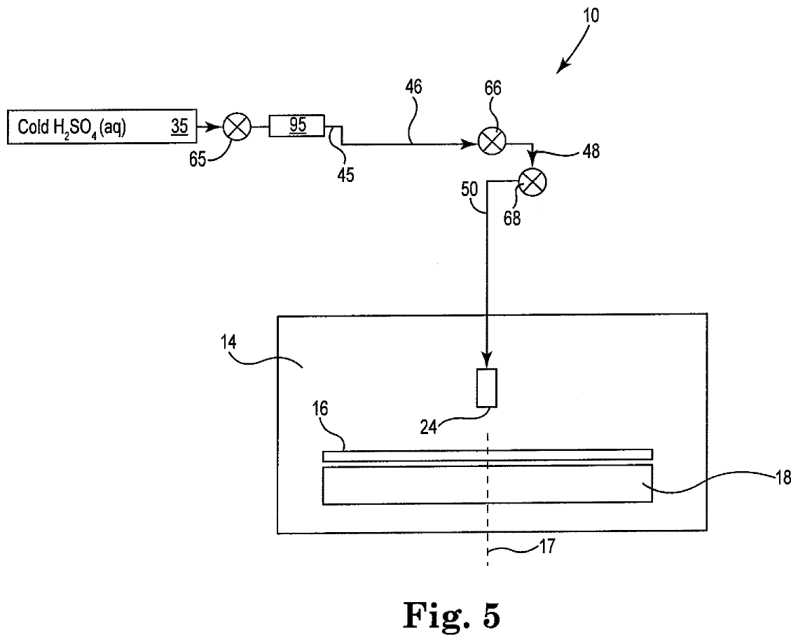

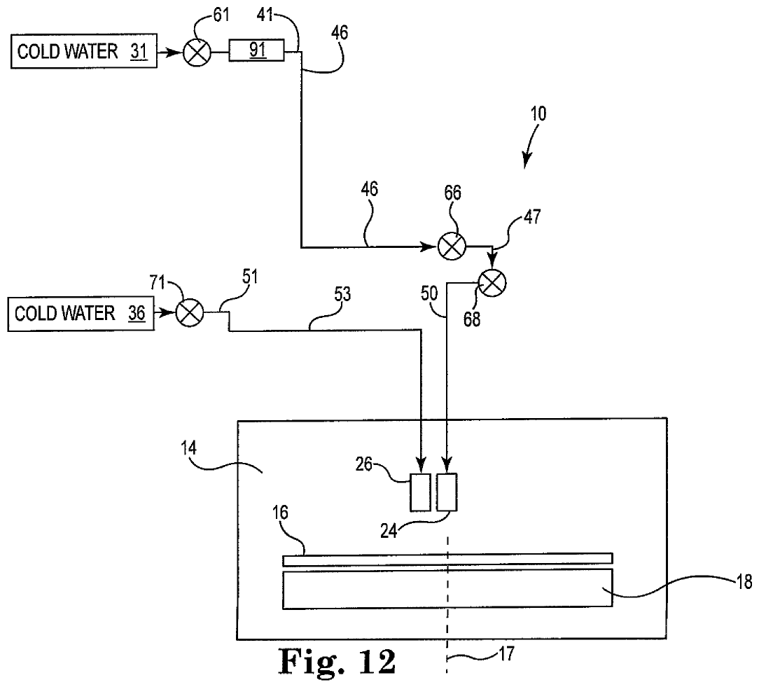

Data obtained from microelectronic workpieces according to FIG. 1 support the microburst theory. In one experiment, microelectronic workpieces incorporating lines of features in the form of polysilicon gates were studied. The workpieces were treated in accordance with the conventional process described below in accordance with FIGS. 5-12. Additionally, after the process shown in FIGS. 5-12 the workpieces were subjected to an SC1 process followed by a rinse and spin-dry. The SC1 process included treatment with an ammonium hydroxide, hydrogen peroxide, and water solution. After performing the conventional process without controlled transitions of the present invention, the surfaces of the workpieces were examined for polysilicon gate damage. Approximately 10 to 20 regions of damage were detected on these workpieces. Most of the damage spanned many lines. The line features in these studies had a 5:1 aspect ratio and were about 150 nm high by about 30 nm wide.

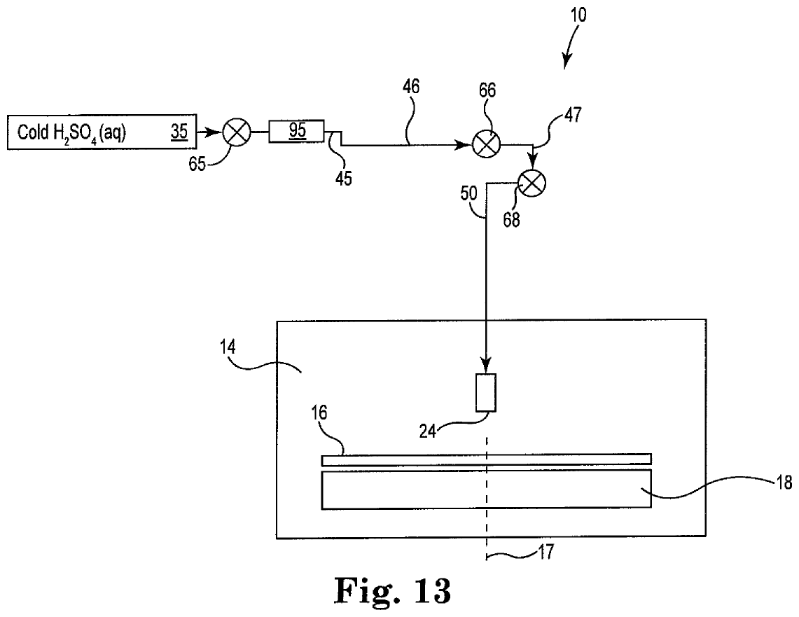

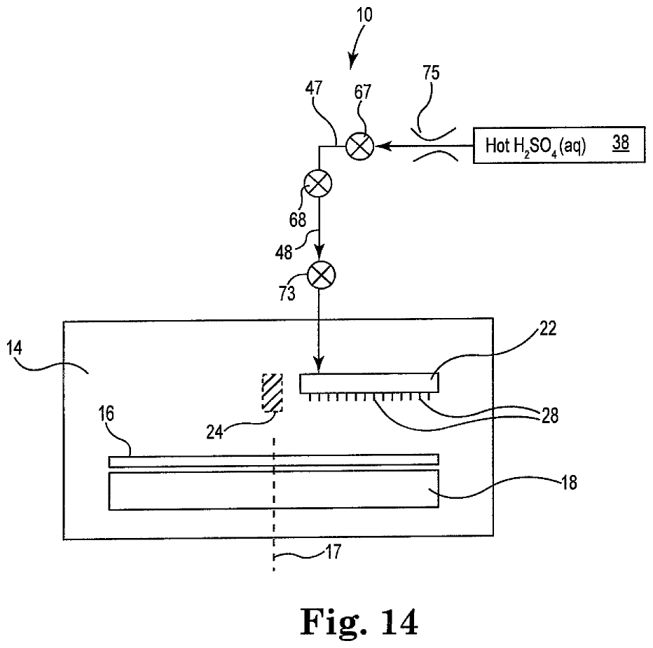

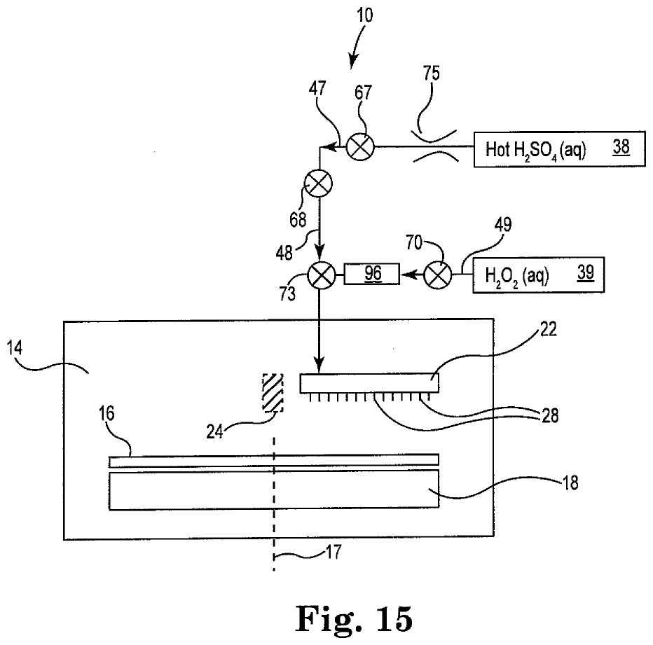

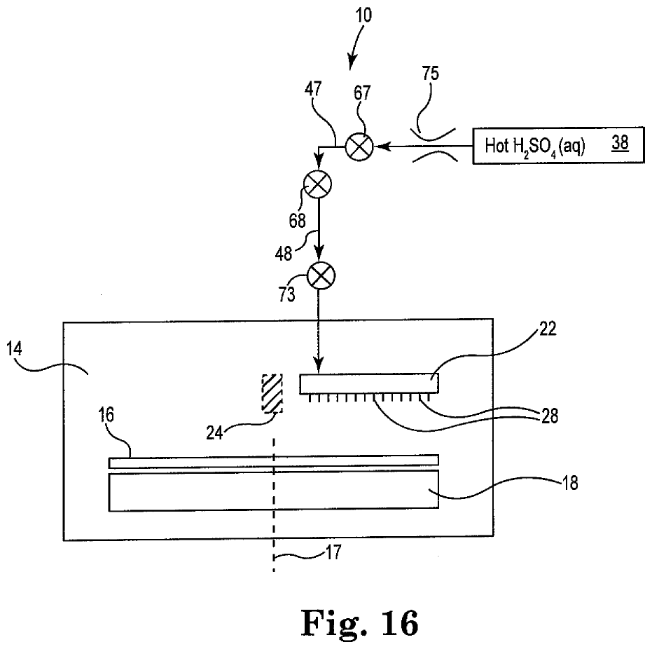

In contrast, when carrying out an improved process with controlled transitions as shown in FIGS. 13-20 on otherwise identical microelectronic workpieces, no damaged areas were detected.

A wide range of treatment fluids may be used in the practice of the present invention as either the first treatment fluid or the second treatment fluid. These include oxidizing fluids, etching fluids, rinsing fluids, polishing fluids, combinations of these and the like. Exemplary fluids include water, aqueous alcohol such as isopropyl alcohol; a liquid containing one or more oxidants such as water that includes ozone, a peroxide, combinations of these, or the like; an acidic liquid such as water containing HF, phosphoric acid, sulfuric acid, nitric acid, HCl, glycolic acid, lactic acid, acetic acid, combinations of these and the like; alkaline solutions such as water that includes dissolved ammonium hydroxide, ammonia, tetramethyl ammonium hydroxide, choline, combinations of these, and the like; buffered solutions such as ammonium fluoride. These compositions may be concentrated or diluted. These compositions may be provided at a wide range of temperatures including temperatures in which the solutions are chilled, supplied at room temperature, or heated.

In view of the microburst theory presented herein that energetic mixing of different chemicals proximal to the microelectronic workpiece surface can be at least part of the cause of feature damage dramatically reduced by the present invention, the present invention is advantageously practiced in those circumstances in which the first and second treatment fluids mix exothermically. Exothermic mixing generally occurs, for instance, when acidic compositions are mixed with other aqueous solutions, including relatively less acidic compositions or acidic compositions including a different kind of acid. Thus, for instance, the well-known piranha solution generally includes sulfuric acid and hydrogen peroxide dissolved in water. The piranha solution is used in one application to clean organic residue, such as photoresist residue, from microelectronic workpiece surfaces. Because the mixture is a strong oxidizer, the mixture will remove most organic matter. The piranha solution also will tend to hydroxylate many surfaces (e.g., add OH groups), making them hydrophilic (water compatible). Piranha compositions also may be used to etch materials such as cobalt, nickel, titanium, tungsten, tantalum and platinum.

The concentration of sulfuric acid and/or hydrogen peroxide in the piranha solutions independently can vary over a wide range from relative concentrated, e.g., over 30% by weight. Moderately diluted solutions also may be used, e.g., those incorporating from more than 0.1 to 30 weight percent of the particular ingredient. Very dilute solutions may be used, e.g., those incorporating from more than 0.001 to 0.1 weight percent of the particular ingredient. Ultra dilute solutions also may be used, e.g., those containing on the order of about one part by weight per billion to 0.001 weight percent of the ingredient. As used herein, the percent by weight of a material in a composition is based upon the total weight of the solution.

Sulfuric acid compositions (without hydrogen peroxide) and piranha compositions (including sulfuric acid and hydrogen peroxide) tend to mix quite energetically and exothermically with water. The energy released upon mixing tends to be greater as the relative concentration of the sulfuric acid increases. Hence, the present invention is very advantageously used in multi nozzle tools that involve a transition between sulfuric acid/piranha treatment and a rinsing treatment. Rinsing often may occur before and/or after the acid treatment.

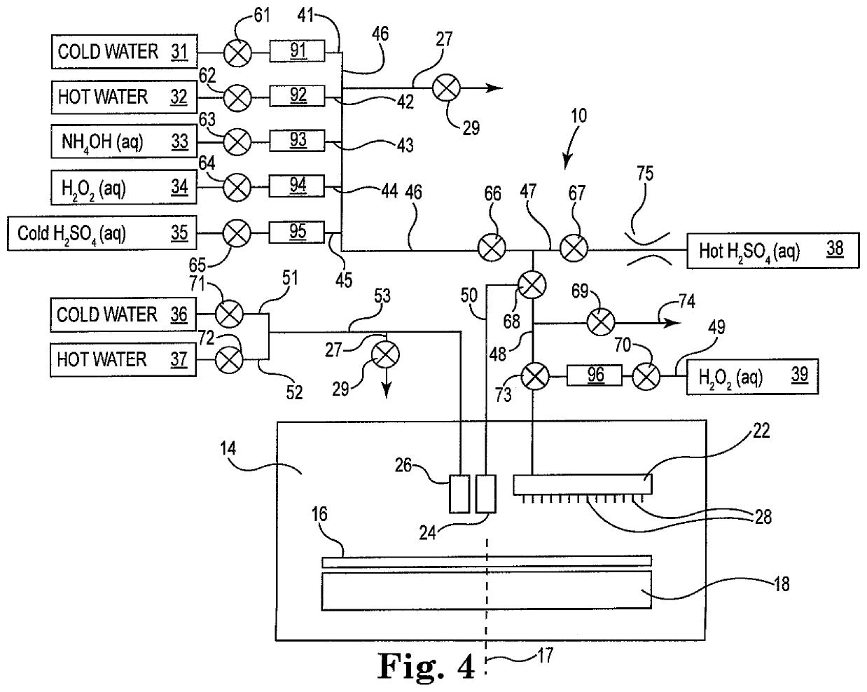

An exemplary apparatus 10 that is particularly suitable for carrying out the present invention is shown in FIG. 4. For purposes of illustration, FIG. 4 schematically corresponds to the ORION® (FSI International, Inc., Chaska, MN) single microelectronic workpiece processing tool. Apparatus 10 generally includes a housing defining process chamber 14. Microelectronic workpiece 16 is supported upon rotating chuck 18. During at least a portion of a multi-step treatment, workpiece spins about axis 17.

Apparatus 10 incorporates multiple, distinct dispense nozzles 22, 24, and 26 that can be independently used to dispense fluids onto the workpiece 16. As illustrated, nozzle 22 comprises a spray bar and generally extends across at least a portion of a chord of the underlying workpiece 16. Apparatus 10 is configured so that this chord generally corresponds to a substantial portion of the radius of the workpiece 16. Spray bar 22 includes a plurality of orifices 28 through which fluid(s) are dispensed through the spray bar generally toward the workpiece 16. Nozzles 24 and 26 independently are used to dispense fluid(s) generally onto the center region of workpiece 16. Inasmuch as workpiece 16 often is spinning during fluid dispenses, the fluids sheet generally radially outward over the workpiece surface before being slung off the perimeter to be collected for discard, recycle, or other use.

Exemplary fluid sources 31 through 39 are coupled to nozzles 22, 24, and/or 26 by plumbing lines 41 through 53. Valves 61 through 73 are used to control the flow of the fluids to the nozzles 22, 24, and 26. For purposes of illustration, sources 31 through 39 include cold (or room temperature) water, hot water, aqueous ammonia, hydrogen peroxide, cold sulfuric acid, and hot sulfuric acid. The multiple sources of cold (or room temperature) water, hot water, hydrogen peroxide, and hot sulfuric may be the same or different. These are shown as separate sources for purposes of clarity. Mass flow controllers 91-96 are used to help control the flow of fluids from sources 31 through 35 and 39. An orifice 75 is used to help control the flow of hot, concentrated (e.g. 96 weight %) sulfuric acid from source 38. As modified to practice embodiments of the present invention, apparatus also includes suction line 74 used to help suction chemicals from nozzles 22 and/or 24. The suction can be generated in a variety of ways (not shown), but conveniently and reliably is provided by aspiration. Other means to generate suction including using a vacuum pump, and the like.

Additional suction lines 27 also may be provided in positions effective to help suction chemicals from all or portions of tool 10. Advantageously, suction can be applied to nozzle 24 via line 74 while chemicals can still be dispensed through nozzles 24 and 26. Valves 29 and 69 help control fluid flow through lines 27 and 74.

FIGS. 5 through 12 show a sequence of steps in which apparatus 10 of FIG. 4 would be used to carry out a prior art method of treatment. From an overall perspective, the sequence first uses sulfuric acid and hydrogen peroxide compositions to remove photoresist residue from microelectronic workpiece 16. A rinsing stage follows the acid treatment. Advantageously, the process is designed to minimize thermal shock of the microelectronic workpiece 16. However, the sequence occurs without controlled mixing at the microelectronic workpiece surface according to the present invention. Without controlled mixing, the process can result in damage of finer features on the microelectronic workpiece surface. FIGS. 13 through 20 show how apparatus 10 of FIG. 4 would be used to carry out an illustrative mode of practice of the present invention incorporating many advantageous principles. Damage of fine features is dramatically reduced. In all these figures associated with the two different sequences, plumbing line(s) and fluid(s) being used in a particular step are shown while other plumbing lines and sources not being used are omitted for purposes of clarity.

The prior art approach shown in FIGS. 5 through 12 will now be described. The sulfuric acid used is concentrated and is about 96% by weight (balance water). The hydrogen peroxide is a 30% by weight aqueous solution. In FIG. 5, microelectronic workpiece 16 is provided on rotating chuck 18. Room temperature, concentrated sulfuric acid (e.g., about 20° C.) is introduced onto microelectronic workpiece 16 via the central dispense nozzle 24. This step occurs for a suitable time such as about ten seconds.

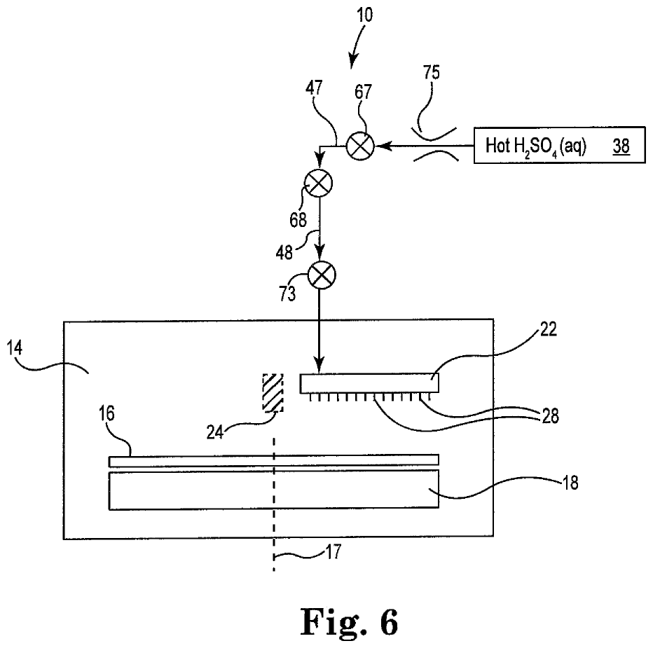

In FIG. 6, the dispense of the cold sulfuric acid stops. Hot concentrated sulfuric acid is now dispensed onto the spinning microelectronic workpiece 16 through nozzle 22. Cold acid might tend to drip from nozzle 24 onto the microelectronic workpiece surface. Nozzle 24 is illustrated with broken lines and lightly cross-hatched to schematically indicate this dripping potential. These drips do not tend to cause any microburst issues inasmuch as the cold acid is merely mixing with hot acid. The hot acid is warmed to a suitable temperature such as 150° C. While flowing from orifice 75 to workpiece 16, some cooling of the hot acid occurs resulting in a temperature at the workpiece surface of about 130° C. This step occurs for a suitable time such as about 5 seconds.

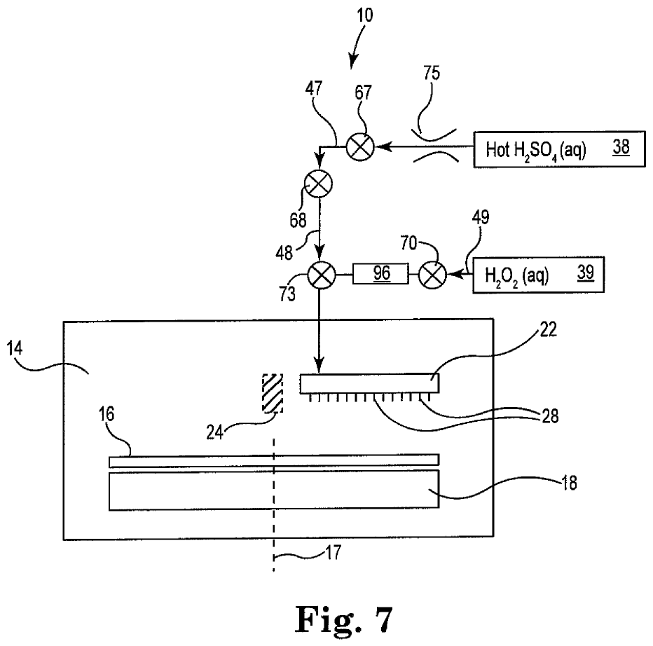

In FIG. 7, the dispense of the hot sulfuric acid continues through the nozzle 22 but is now dispensed in combination with hydrogen peroxide. Hot sulfuric acid and hydrogen peroxide potentially can mix energetically. However, this mixing is not a concern with respect to device damage under a microburst theory inasmuch as the mixing occurs inside the plumbing upstream from the nozzle 22. This is well before the mixture is dispensed and reaches the microelectronic workpiece 16. Due to the heat of mixing, the temperature may increase during this step such as to 200° C. In a typical treatment, the volume ratio of concentrated sulfuric acid aqueous hydrogen peroxide is 4:1. This step occurs for a suitable time period such as about 80 seconds. Dripping of residual cold acid from nozzle 24 may or may not still occur during at least a portion of this step but is not shown in FIG. 7.

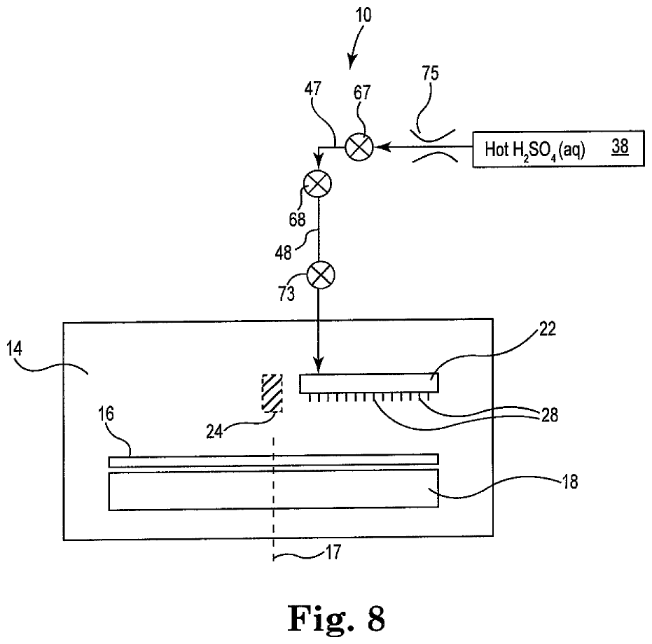

In FIG. 8, the dispense of the hot sulfuric acid continues through the nozzle 22, but hydrogen peroxide is no longer mixed with the acid. The dispense temperature drops such as to about 130° C. This step may occur for a suitable time such as about 5 seconds.

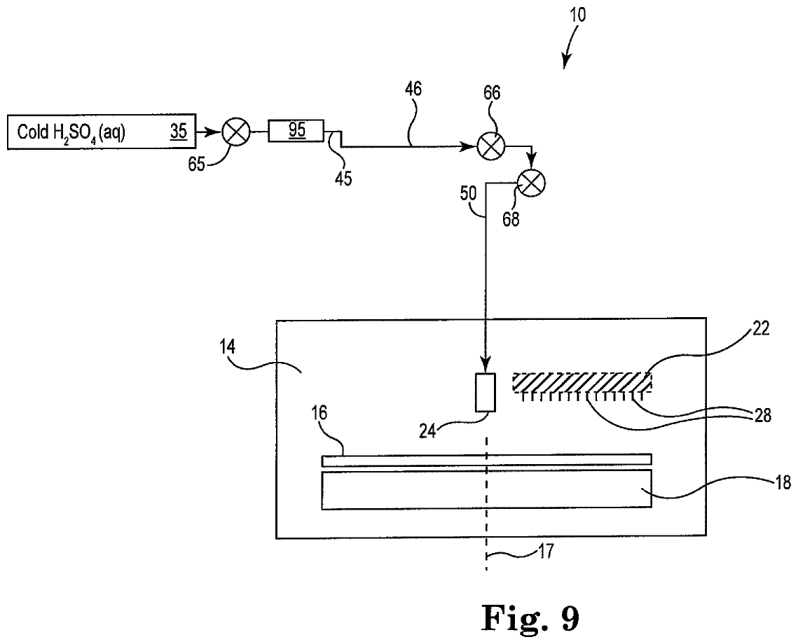

In FIG. 9, a transition is made from hot sulfuric acid solution back to room temperature sulfuric acid solution. The flow of hot sulfuric acid through the nozzle 22 stops and room temperature sulfuric acid is dispensed through central nozzle 24. The nozzle 22 includes some residual, hot sulfuric acid as shown by the broken line and light cross-hatching, but not all of the hot sulfuric acid solution drains from the nozzle 22. Some of the residual, hot sulfuric acid solution might drip onto the workpiece surface. This is not an issue under a microburst theory, as the hot sulfuric acid is merely mixing with similar but room temperature sulfuric acid proximal to the workpiece surface. Transitioning to room temperature sulfuric acid reduces the temperature at the workpiece surface such as to a temperature of about 20° C. This step occurs for a suitable time period such as about 15 seconds.

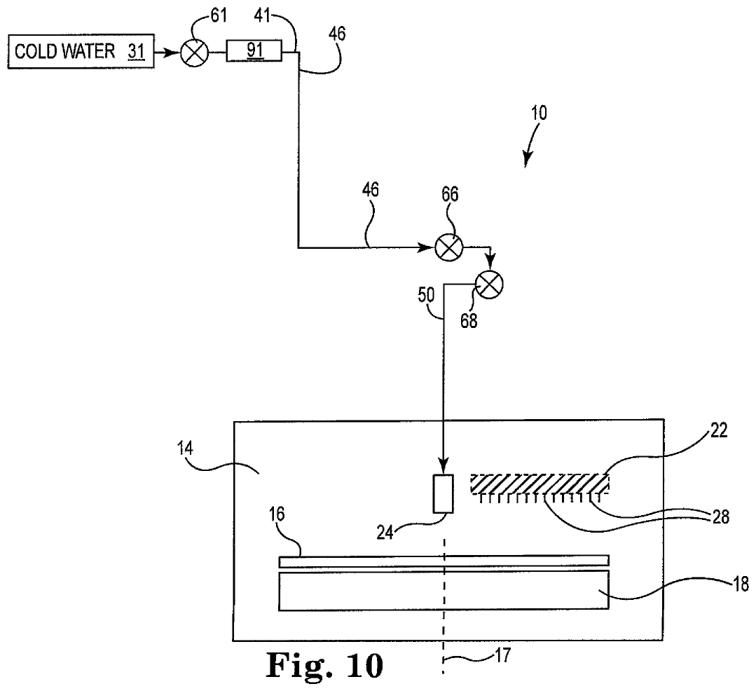

In FIG. 10, the treatment transitions from an acid dispense to a rinse water dispense. This is a stage at which the risk of microburst damage increases. Water (preferably at about 20° Celsius) is dispensed onto the center of the microelectronic workpiece 16 through the central dispense nozzle 24. The acid solution on the microelectronic workpiece surface is rinsed away and replaced with a radially sheeting film of water as this rinsing step continues for a suitable time period such as about 7 seconds. The water is at a suitable temperature such as about 20° C. In the meantime, residual, hot sulfuric acid solution may still remain in the nozzle 22. This residual acid solution can drip into the film, proximal to the microelectronic workpiece surface. Potential microbursts and corresponding feature damage can occur at sites where these drips occur.

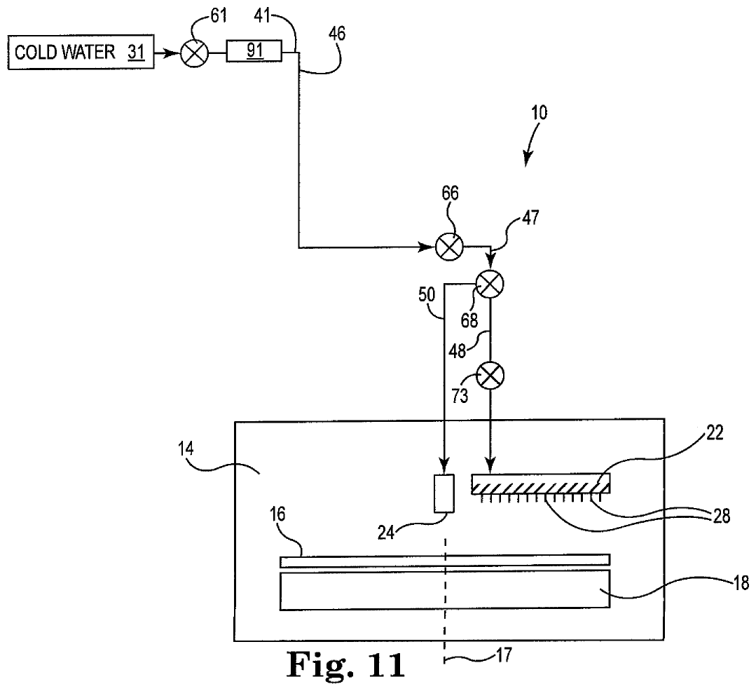

The risk of microburst damage continues in FIG. 11. The water dispense through nozzle 24 is stopped. Instead, the water is used to flush nozzle 22. This creates a risk of microburst damage in at least two ways. First the flushing of nozzle 22 initially pushes acid rich solution out of the nozzle 22 and onto the water-rich surface of workpiece 16. This allows the mixing of flushed acid and water to occur at the microelectronic workpiece surface. Second, as the surface becomes temporarily acid rich during the initial stage of the flushing of nozzle 22, residual water from nozzle 24 can drip onto the acid rich surface, where the mixing of the acid and water could result in microbursts and corresponding damage. In short, the residual acid in the nozzle 22 is a potential factor contributing to microburst damage at the microelectronic workpiece surface. The water dispense of this step occurs for a suitable time such as about 21 seconds. At the end of this step, the microelectronic workpiece surface is generally covered with sheeting water and no acid remains.

In step 12, water is flushed through both nozzles 22 and 24. Because the microelectronic workpiece surface is now covered with water generally, the dispensed water mixes only with water at the surface. Substantially no risk of microburst damage is present at this stage.

After carrying out the sequence of steps described above the microelectronic workpiece 16 can be further processed or otherwise handled as desired. For instance, according to one option, the microelectronic workpiece may be subjected to a so-called treatment including an SC1 treatment (mixture of aqueous ammonium hydroxide, aqueous hydrogen peroxide, and water) followed by rinsing and drying.

FIGS. 13 through 20 show how the apparatus 10 and treatment of FIGS. 5 through 12 can be modified to dramatically reduce the risk of microburst damage using principles of the present invention. As an equipment modification, apparatus 10 is fitted with a suction line 74 so that suction can be applied to the plumbing lines and nozzles 22 and 24 fluidly coupled to this line 74.

FIGS. 13 through 16 generally illustrate process steps that are carried out in the same manner as the steps shown in FIGS. 5 through 8, respectively.

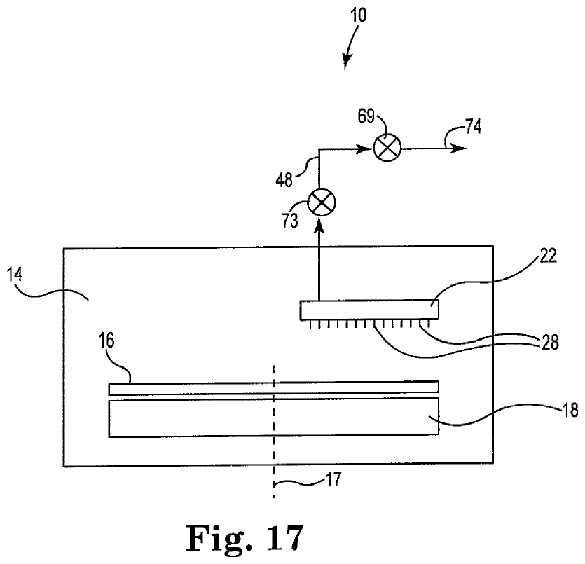

The process step illustrated in FIG. 17 recognizes that residual, hot sulfuric acid in nozzle 22 has the potential to drip onto microelectronic workpiece 16 and cause microburst damage. Accordingly, in this step, the dispense of hot sulfuric acid solution through nozzle 22 is stopped, and suction is applied to nozzle 22 in order to remove residual acid solution through line 74. This causes the nozzle 22 to be generally substantially completely dry so that the risk of acid drops is minimized. During this step, water is not yet dispensed onto the microelectronic workpiece through any nozzle to minimize a risk that acid drops could fall and mix with water proximal to the microelectronic workpiece surface. It is possible in the early stages of this step that a film of acid solution dispensed from previous step(s) could remain on the microelectronic workpiece surface. Accordingly, the microelectronic workpiece desirably continues to spin in order thin down this residual film and or to make the surface as acid-free as is desired. This step occurs for a suitable time period such as about 5 seconds. The temperature of the microelectronic workpiece surface remains at about 130° C. during this step, or the surface may cool somewhat as the microelectronic workpiece spins.

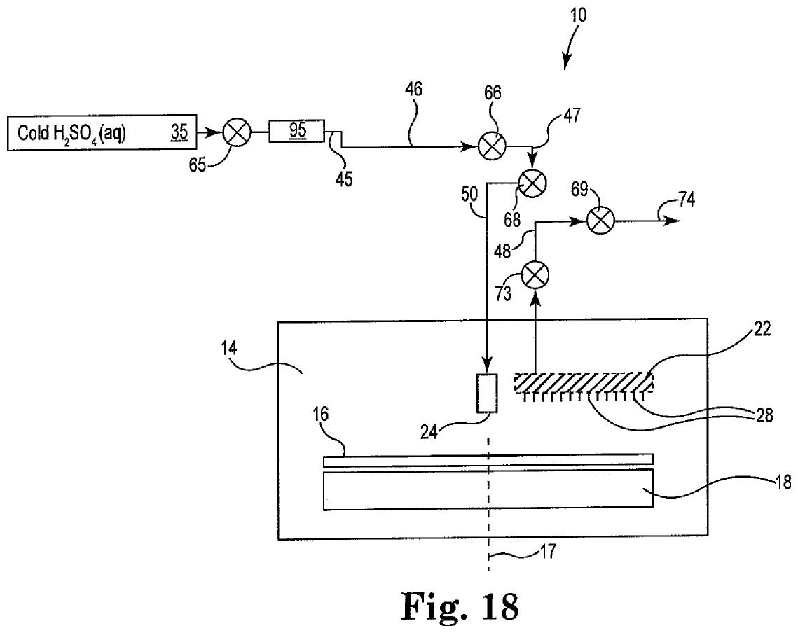

In FIG. 18, an optional process step is illustrated and can be used after the process step illustrated in FIG. 17 if desired. This optional step involves dispensing a relatively cool chemical such as cold sulfuric acid and/or aqueous hydrogen peroxide. The temperature of the dispensed material desirably is less than about 60° C., preferably less than about 50° C., more preferably less than about 30° C. As shown, dispense of room temperature sulfuric acid through central nozzle 24 is started and suction applied to nozzle 22 is maintained in order to remove any residual acid solution in line 74. The nozzle 22 may include some residual, hot sulfuric acid as shown by the broken line and light cross-hatching. Transitioning to room temperature sulfuric acid reduces the temperature at the workpiece surface such as to a temperature of about 20° C. This step occurs for a suitable time period such as about 15 seconds.

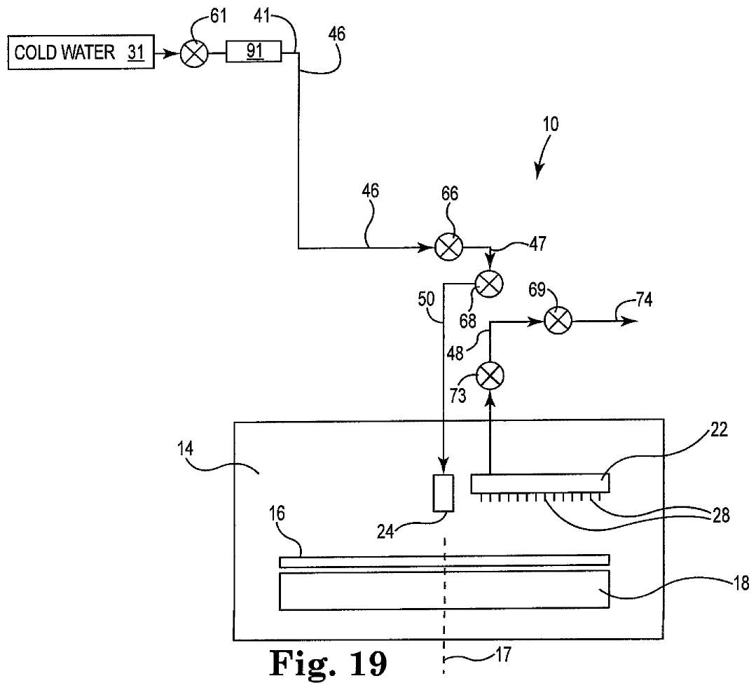

In the next step of FIG. 19, it is desirable that suction continues to be pulled on nozzle 22 to continue to minimize the risk of acid drips. Indeed, this suction can be maintained generally continuously until stopped during the course of or at the and of the step shown in FIG. 19 unless otherwise noted. Water is now safely dispensed onto generally the center region of the micro-electro-workpiece 16 through nozzle 24. The centrally dispensed water can be viewed as creating a fluid wave that washes radially outward over the microelectronic workpiece surface. If there is a heat of mixing between the acid and water, the heat of mixing is spread out over a relatively large volume. To the extent that any residual acid remains on the surface of the microelectronic workpiece 16, it is believed that this central dispense of water helps to minimize the risk of microburst damage. This step occurs for a suitable time such as about 20 seconds. The water dispense cools the workpiece 16 to a temperature such as about 20° C.

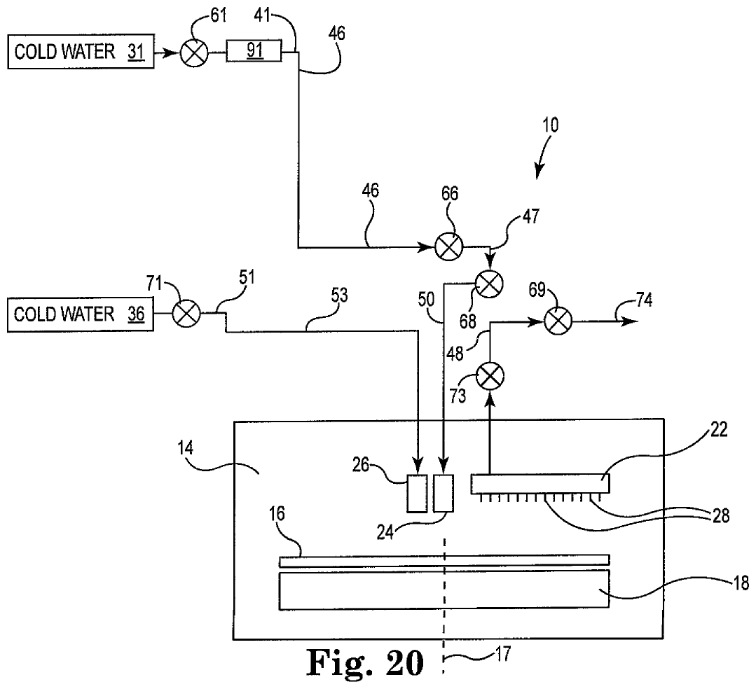

The optional step shown in FIG. 20 involves continuing the dispense and aspiration occurring in the step of FIG. 19 with the additional step of dispensing cold or hot water through nozzle 26. This is not essential but can be practiced if desired to rinse chemicals that might be present in nozzle 26 from a prior step not described here. Aspiration can be stopped during or at the end of this step. This step occurs for a suitable time such as about 3 seconds. The microelectronic workpiece is at a temperature corresponding to the temperature of the dispensed water, such as about 20° C.

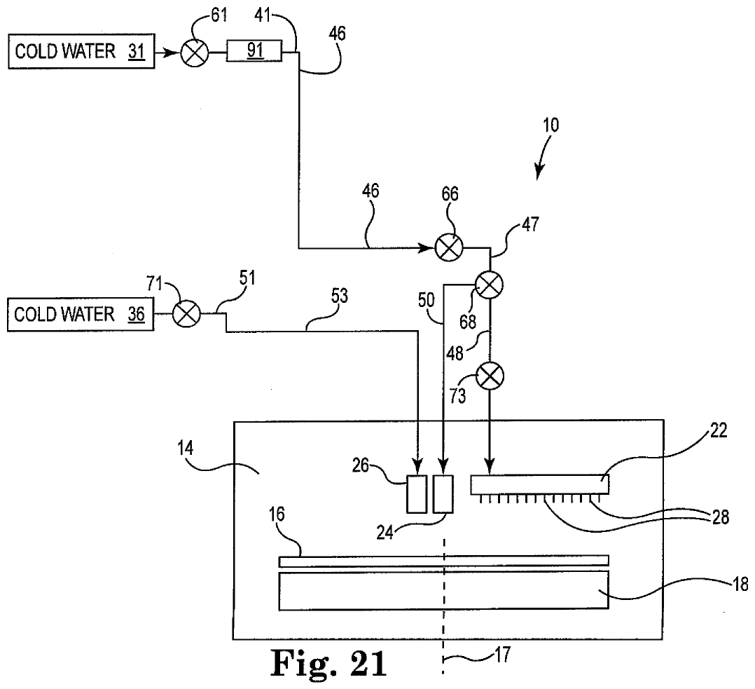

FIG. 21 shows a step in which water is used to rinse the nozzle 22 in preparation further process of microelectronic workpiece 16 and/or other micro electronic workpieces. Optionally, nozzles 24 or 26 also may continue to be rinsed if desired. As shown, nozzle 26 continues to be rinsed with water. There may be very minor amounts of acid remaining in the nozzle 22 or in the upstream plumbing, but the risk of microburst damage is very low. Because there generally is so little acid, if any, the water easily mixes with any such acid prior to reaching the microelectronic workpiece surface.

After carrying out the sequence of steps shown in FIGS. 13 to 21, the microelectronic workpiece 16 can be further processed or otherwise handled as desired. For instance, according to one option, the microelectronic workpiece may be subjected to a so-called treatment including an SC1 treatment followed by rinsing and drying.

In addition, the sequence of steps shown in FIGS. 13 to 21 can be carried out with the additional dispense of water vapor or steam into the process chamber during the dispense of the mixture of sulfuric acid and hydrogen peroxide as described in U.S. Pat. No. 7,592,264 to Christenson et al. and having application Ser. No. 11/603,634 and in co-pending U.S. patent application Ser. No. 12/152,641 to DeKraker et al. filed on May 15, 2008. Also, the volume ratio of concentrated sulfuric acid to aqueous hydrogen peroxide dispensed during the step illustrated in FIG. 7 can be adjusted from 2:1 to 10:1 depending on the desired outcome of the process, with a 10:1 ratio being most desirable for a process that includes the dispense of water vapor or steam and 4:1 being most desirable for a process that does not include water vapor or steam. Also, a volume ratio of concentrated sulfuric acid to aqueous hydrogen peroxide of 2:1 or 4:3 is most desired for processes in which the goal is to etch metal, such as platinum.

The following patent documents are incorporated by reference herein in their entirety and for all purposes.
U.S. Pat. No. 7,556,697 to Arne C. Benson et al., issued Jul. 7, 2009 and entitled SYSTEM AND METHOD FOR CARRYING OUT LIQUID AND SUBSEQUENT DRYING TREATMENTS ON ONE OR MORE WAFERS.
U.S. Publication No. 2007/0022948 to Alan D. Rose et al., published Feb. 1, 2007 and entitled COMPACT DUCT SYSTEM INCORPORATING MOVEABLE AND NESTABLE BAFFLES FOR USE IN TOOLS USED TO PROCESS MICROELECTRONIC WORKPIECES WITH ONE OR MORE TREATMENT FLUIDS.
U.S. Publication No. 2007/0245954, Jimmy D. Collins et al., published Oct. 25, 2007 and entitled BARRIER STRUCTURE AND NOZZLE DEVICE FOR USE IN TOOLS USED TO PROCESS MICROELECTRONIC WORKPIECES WITH ONE OR MORE TREATMENT FLUIDS.
U.S. Publication No. 2008/0008834 to Jimmy D. Collins et al., published Jan. 10, 2008 and entitled BARRIER STRUCTURE AND NOZZLE DEVICE FOR USE IN TOOLS USED TO PROCESS MICROELECTRONIC WORKPIECES WITH ONE OR MORE TREATMENT FLUIDS.
U.S. Publication No. 2008/0283090 to David DeKraker at al., published Nov. 20, 2008 and entitled PROCESS FOR TREATMENT OF SUBSTRATES WITH WATER VAPOR OR STEAM.
U.S. Publication No. 2009/0038647 to David DeKraker et al., published Feb. 12, 2009 and entitled RINSING METHODOLOGIES FOR BARRIER PLATE AND VENTURI CONTAINMENT SYSTEMS IN TOOLS USED TO PROCESS MICROELECTRONIC WORKPIECES WITH ONE OR MORE TREATMENT FLUIDS.
U.S. Publication No. 2009/0280235 to Jeffrey M. Lauerhaas at al., published Nov. 12, 2009 and entitled TOOLS AND METHODS FOR PROCESSING MICROELECTRONIC WORKPIECES USING PROCESS CHAMBER DESIGNS THAT EASILY TRANSITION BETWEEN OPEN AND CLOSED MODES OF OPERATION.
U.S. Pat. No. 7,592,264, to Kurt Karl Christenson, issued Sep. 22, 2009 and entitled PROCESS FOR REMOVING MATERIAL FROM SUBSTRATES.

The present invention has now been described with reference to several exemplary embodiments thereof. The entire disclosure of any patent or patent application identified herein is hereby incorporated by reference for all purposes. The foregoing disclosure has been provided for clarity of understanding by those skilled in the art of vacuum deposition. No unnecessary limitations should be taken from the foregoing disclosure. It will be apparent to those skilled in the art that changes can be made in the exemplary embodiments described herein without departing from the scope of the present invention. Thus, the scope of the present invention should not be limited to the exemplary structures and methods described herein, but only by the structures and methods described by the language of the claims and the equivalents of those claimed structures and methods.

1-27. (canceled)

28. A method of removing a photoresist from a surface of a microelectronic workpiece with a first acid treatment fluid dispensed from a first dispense nozzle and an aqueous rinsing fluid subsequently dispensed from a second, independent dispense nozzle in a manner that includes a transition between dispensing the first acid treatment fluid and dispensing the aqueous rinsing fluid that is controlled to prevent drips of the first acid treatment fluid from falling from the first dispense nozzle and mixing with the aqueous rinsing fluid proximal to the surface of the microelectronic workpiece, the method comprising:
a) spinning the microelectronic workpiece in a process chamber, wherein the spinning microelectronic workpiece underlies the first and second dispense nozzles;
b) dispensing the first acid treatment fluid through the first dispense nozzle onto the underlying spinning microelectronic workpiece, wherein the first acid treatment fluid has a temperature that is hot enough such that dispensing the first acid treatment fluid through the first dispense nozzle onto the underlying, spinning microelectronic workpiece removes the photoresist from the surface;
c) while the microelectronic workpiece is spinning, terminating dispensing of the first acid treatment fluid through the first dispense nozzle, wherein the surface of the microelectronic workpiece includes a residual film of the first acid composition upon terminating dispensing of the first acid treatment fluid,
d) while the microelectronic workpiece is spinning and prior to dispensing the aqueous, rinsing fluid, applying a suction to the first dispense nozzle for a suitable time period to remove a residual amount of the first acid treatment fluid from inside the first dispense nozzle and to thin down the residual film of the first acid treatment fluid on the surface of the spinning microelectronic workpiece; and
e) after the suitable time period and while applying suction to the first dispense nozzle and while the wafer is spinning, dispensing the aqueous rinsing fluid from the second dispense nozzle onto a central region of the surface of the spinning microelectronic workpiece, wherein the suction applied to the first dispense nozzle while dispensing the aqueous rinsing fluid from the second dispense nozzle reduces the risk that the first acid treatment fluid drips from the first dispense nozzle to mix with the aqueous rinsing fluid proximal to the surface of the spinning microelectronic workpiece.

29. The method of claim 28, wherein the microelectronic workpiece comprises features having an aspect ratio of at least 5:1.

30. The method of claim 1, wherein the aqueous rinsing fluid is water.

31. The method of claim 28, wherein the first acid treatment fluid comprises an aqueous acid.

32. The method of claim 28, wherein the first acid treatment fluid comprises sulfuric acid.

33. The method of claim 28, wherein the first acid treatment fluid comprises phosphoric acid.

34. The method of claim 28, further comprising, after step d) and prior to step e), while the microelectronic workpiece is spinning and suction is applied to the first dispense nozzle, dispensing an additional acid composition through the second dispense nozzle, wherein the additional acid composition dispensed from the second dispense nozzle is at a temperature such that dispensing the additional acid composition cools the surface of the microelectronic workpiece.

35. The method of claim 28, further comprising a barrier plate structure comprising the first and second dispense nozzles, wherein the barrier plate structure overlies the spinning microelectronic workpiece, and wherein the barrier plate structure is moveable in a z-axis relative to the spinning microelectronic workpiece.

36. The method of claim 28, wherein the first acid treatment fluid comprises sulfuric acid and hydrogen peroxide.

37. The method of claim 28, wherein the first dispense nozzle is coupled to a first dispense line and the suctions in steps d) and e) are applied to the first dispense line.

38. The method of claim 28, further comprising, after the step e), dispensing a rinsing liquid through the first dispense nozzle.

39. The method of claim 38, wherein the rinsing liquid is dispensed through the first dispense nozzle while the microelectronic workpiece is spinning.

40. The method of claim 28, wherein the first dispense nozzle is in the form of a spray bar comprising a plurality of nozzle orifices.

41. The method of claim 28, further comprising the step of cooling the microelectronic workpiece after step d) and prior to step e).

42. The method of claim 28, further comprising, after step a) and prior to step b) dispensing a room temperature acid composition onto the spinning microelectronic workpiece through the first dispense nozzle.

43. The method of claim 1, wherein the first acid treatment fluid comprises sulfuric acid and the method further comprises, after step d) and prior to step e) cooling the spinning microelectronic workpiece by dispensing a composition comprising sulfuric acid through the second dispense nozzle, wherein the cooling occurs while a suction is applied to the first dispense nozzle.
